(19) United States
(12) Patent Application Publication
(10) Pub. No.: US 2015/0001922 A1
(43) Pub. Date: Jan. 1, 2015

(54) POWER DOWN SIGNAL FOR PORT OF NETWORK DEVICE

(71) Applicant: Hewlett-Packard Development Company, L.P., Houston, TX (US)

(72) Inventors: Tzye Perng Poh, Singapore (SG); Boon Siang Choo, Singapore (SG); Jing Kai Tan, Singapore (SG)

(21) Appl. No.: 13/929,453

(22) Filed: Jun. 27, 2013

(51) Int. Cl. H02J 1/00; H05K 9/00

(52) U.S. Cl. CPC H02J 1/00; H05K 9/00
USPC 307/1; 307/125

(57) ABSTRACT

A network device including a power supply, a communication port and a power line between the power supply and the communication port. A controller is to turn on a switch so that power can be delivered to the communication port along a second power line parallel to the first power line, before sending a power down signal.

### BACKGROUND

Network devices include for example network switches and routers which forward data in a network according to a destination address or other traffic forwarding policies. A network device may have a plurality of ports for receiving and sending data over a wired link. A network device with Power over Ethernet (PoE) capability has a plurality of PoE ports which are able to deliver not only data but also power to external devices connected to the port.

### BRIEF DESCRIPTION OF THE DRAWINGS

Examples of the invention will now be described, by way of non-limiting example only, with reference to the accompanying drawings, in which:

FIG. 1 shows an example structure of a network device;

FIG. 2 shows another example structure of a network device;

FIG. 3 shows an example method of reducing a voltage transient when turning off power to a port of a network device;

FIG. 4 shows an example of a noise reduction circuit;

FIG. 5 shows an example of a port power controller.

### DETAILED DESCRIPTION

FIG. 1 is a schematic diagram showing an example of a network device. The network device includes a power supply 10 to supply power to components 30 of the network device including a controller 40.

The power supply 10 may supply power at a relatively higher voltage (for instance 54V). Therefore a DC to DC converter 20 may be used to convert the power to a lower voltage (e.g. 12V) for use by the components of the network device including controller 40. Other components of the network device which draw power from the power supply may include a CPU to carry out higher level functions, a memory for storing a forwarding table and a forwarding chip such as an ASIC to forward data packets in accordance with the forwarding table.

The network device has a plurality of communication ports 70 for sending and receiving data over a wired link, such as a cable. These ports may for example be designed to receive a RJ45 or other jack from a wired link such as a cable for communicating data signals. The ports may for example be Ethernet ports. One, some or all of the ports may be capable of transmitting power to an external device as well as sending and receiving data. Power over Ethernet (PoE) is one example of a standard which is used to deliver power over a wired data link. Ports using this PoE standard are referred to as PoE ports.

To enable the ports 70 to supply power to an external device there is a first power line 60 for conducting power from the power supply 10 to the ports 70. Because the ports 70 are used for communicating data as well as power, it is desirable to minimize noise. Noise may for example be generated by the DC to DC converter 20. DC to DC converters often use a PWM (Pulse Width Modulation) device which generates noise and may be propagated along the power lines, including line 60, to the ports 70. To prevent or reduce noise being communicated to the ports 70, the power line 60 includes an inductor 62 which acts as a noise filter. The inductor may for example be a choke. A choke is a coil made of wire, which may be wound around a magnetic core, and which acts an inductor to block high frequency alternating current.

In some situations the network device may wish to shut down the power delivery capability of the communication ports 70. For example if the power supply becomes overloaded then the ports may stop delivering power to external devices so that the available power is conserved for other functions. This may be accomplished by sending a power down signal. A power down signal is a signal instructing delivery of power by the ports to external devices to be stopped. An example is a Rapid Power Down (RPD) signal which is used in some PoE capable devices. The signal may be sent by a controller 40 of the network device. The controller 40 may for instance be implemented by a microprocessor, ASIC (Application Specific Integrated Chip) or FPGA (Field Programmable Gate Array).

As the power down is relatively rapid this can create a large voltage transient in the inductor 62. A large voltage transient risks causing damage to electronic circuitry in the network device. For example, it may cause damage to the DC to DC converter or other components of the network device. Further, any communication ports which are not turned off may also receive the voltage transient. For example, if a plurality of ports are supplied power through the same inductor 62, then if power to one of the ports is turned off this will create a voltage transient in the inductor 62 which may generate a large voltage at the ports which are still on. This may be undesirable for safety reasons and may violate standards as to the highest voltage level which should be delivered from a communication port.

According to the present disclosure, as shown in FIG. 1, a second power line 50 is provided between the power supply 10 and the ports 70. The second power line may be switched on by a switch 52, such as a transistor or any other electronically activated switch. When the switch 52 is ON, power can flow in parallel from the power supply 10 to the ports down both the first 60 and second 50 power lines. When the switch 52 is OFF, power has to flow down the first power line and cannot flow down the second power line as the conductive path of the second power line is broken by the switch 52 being OFF.

By turning the switch 52 ON shortly before sending a power down signal, for a port and turning the switch 52 OFF after the power down operation is completed, the voltage transient can be reduced. In effect the voltage transient is smoothed as the power goes from being delivered on the first power line to being delivered on both the first and second power lines to being shut off. The voltage across the inductor 62 is thus reduced more gradually, which has the effect of smoothing the voltage transient. More specifically, after the switch 52 is turned on, power delivery is shared by the first power line 60 and second power line 50. The current flowing through the inductor 62 is thus reduced compared to the situation if power is flowing through only the first power line 60. Thus when the power down operation is activated and power is no longer delivered to a port 70, the reduction in current through the inductor 62 di/dt is less, compared to the case if all the power was delivered through first power line 60 before turning off the power. The transient voltage V generated in an inductor by change in current is V=−(L*di/dt). Therefore by switching on the parallel path 50 before turning off the power, the transient voltage generated in the inductor 62 and felt by other components of the network device is reduced.

The control signal 45 to switch ON and OFF the switch 52 and the power down signal 47 for the ports may be controlled by the controller 40 and will be discussed in more detail later.

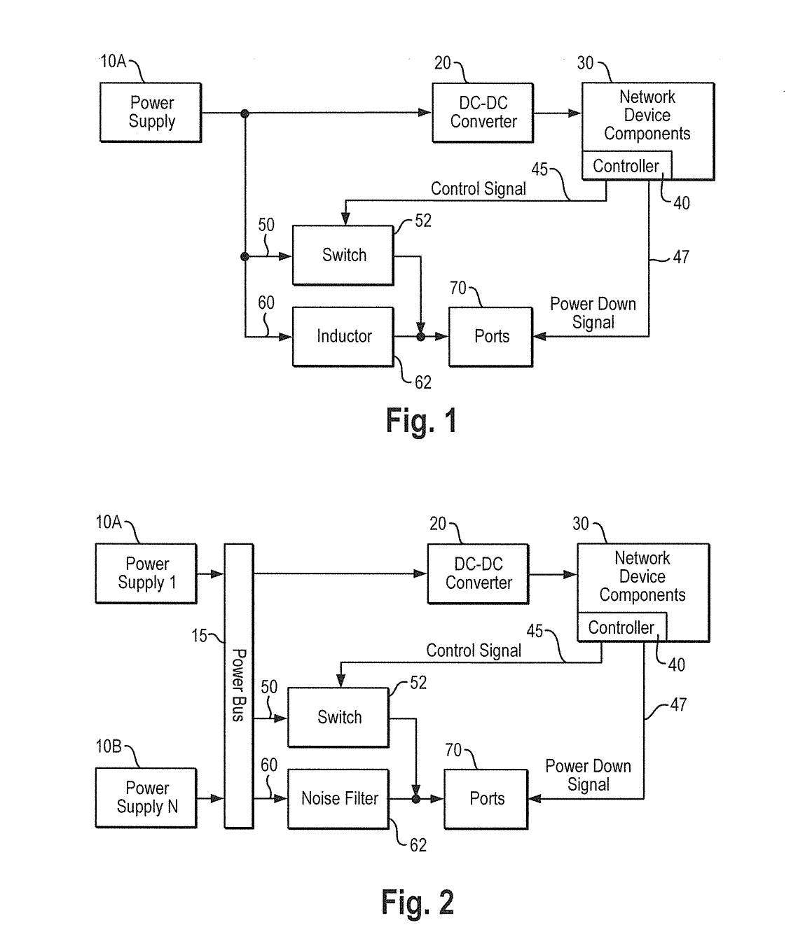

FIG. 2 shows another example of a network device, similar to FIG. 1 but having a plurality of power supplies 10A, 10B. The power from the power supplies is pooled for instance by a power bus 15. In other examples the mechanism for pooling the power of the power supplies may have additional circuitry to control or prevent flows of power in unwanted directions. For example, a forward bias diode may be placed between each power supply and the power sharing bus 15, this prevents any back flow of current between the power supplies. While only two power supplies are shown in FIG. 2, it is to be understood that there may be more than two power supplies. Further, in FIG. 2, the inductor 62 is described as a noise filter which includes an inductor.

The power down signal is sent in respect of one or more ports. All the ports which are capable of delivering power may have their power shut down at the same time, or only some of the ports may have their power delivery shut down. The power down signal may cause the delivery of high voltage power to the port to be cut off, or otherwise prevent the port from delivering power to an external device. The power down signal may be sent to a port or ports and handled by each port individually, or may be sent to a port power controller. A port power controller controls the delivery of power to a plurality of ports and will be explained in more detail later.

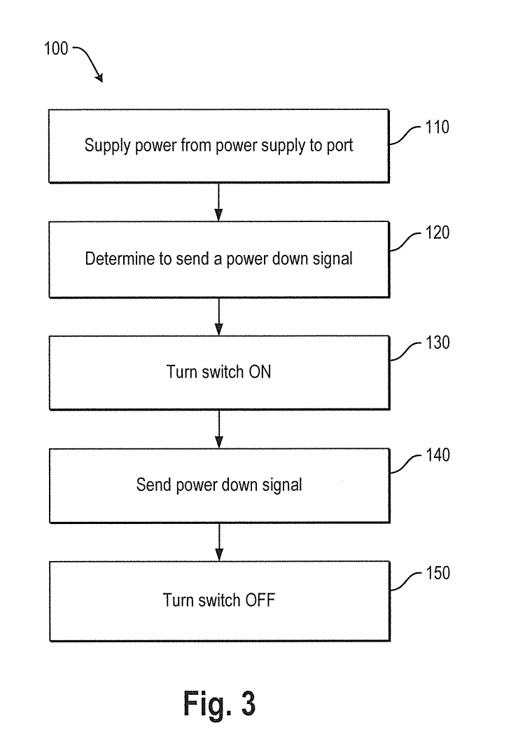

A method of operation 100 will now described with reference to FIG. 3.

At block 110 power is supplied to a port or ports from the power supply. The power supplied to the port or ports may be at a higher voltage, for instance before down conversion by a DC to DC converter which is used to supply power at a lower voltage to other internal components of the network device.

At block 120 it is determined to send a power down signal to stop provision of power to external devices by the port or ports. The determination to send this signal may for instance be made by a network device controller such as the controller 40 shown in FIGS. 1 and 2. The determination may for instance be made in response to the network device needing to conserve power for other functions, or the power supply becoming overloaded. If there are plurality power supplies, then the determination to send a power down signal to the power providing ports may be in response to one of the power supplies becoming overloaded or failing. If one of the plurality of power supplies fails then a reduced amount of power is available and so non-essential, but power intensive functions, such as PoE can be shut down.

At block 130 the controller 40 sends a control signal to the switch 52 to turn the switch ON. As explained above, this completes a parallel path 50 by which power may be delivered to the port or ports 70.

At block 140 the controller 40 sends a power down signal for the port or ports 70. The power down signal is a signal instructing provision of high power to a port for use by external devices to be stopped. It may for instance be a Rapid Power Down signal. The power down signal may be sent to the port itself, or to a power down controller, such as a PoE controller, which controls provision of power to one or more ports. The power down signal is sent shortly after the switch ON control signal is sent to the switch 52 in block 130. For example the power down signal may be sent immediately following the switch ON control signal or a few micro seconds after.

At block 150 the controller sends a switch OFF control signal to the switch 52 to turn the switch OFF. Turning the switch 52 OFF breaks the second parallel path 50 from the power supply to the port. The switch OFF control signal is sent after the power down signal of block 140. The switch OFF control signal may be sent after the power down operation has been completed. For instance, the switch OFF control signal may be sent after receiving an acknowledgement signal from a port or port power controller indicating that the power down operation has been completed. The power down operation is the turning off of power to a port for use by an external device, for instance by cutting a circuit linking the port to the power supply.

In another example the switch OFF control signal may be sent a short predetermined period of time after the power down signal was sent by the controller in block 140. The short predetermined period of time may for instance be a few micro seconds (e.g. 1-5 microseconds).

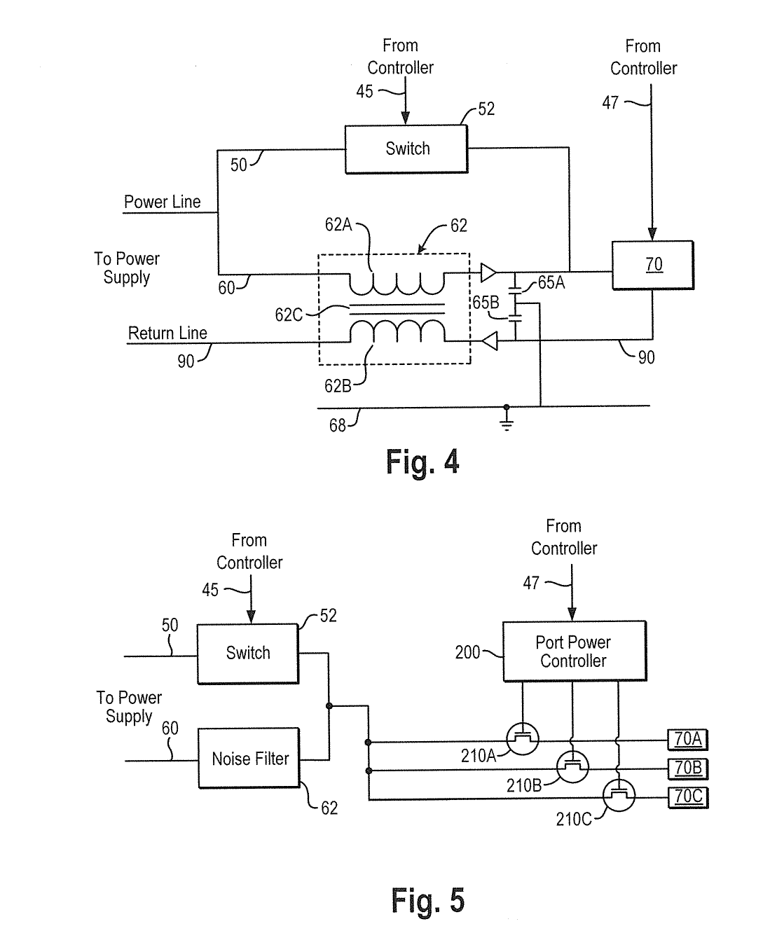

FIG. 4 shows an example of a noise filter circuit 62 in more detail. The noise filter circuit may be used in the network device of FIG. 1 or FIG. 2, in place of the component denoted by reference numeral 62 in those Figures. The circuit 62 includes an inductor in the form of a choke. In this example the choke is a common mode choke. A common mode choke is a choke which is designed to filter out common mode noise that is noise which travels in the same direction on both power input and return lines. The common mode choke may include a first coil 62A and a second coil 62B which are wound in opposite directions around a common core 62C. The common mode choke has the effect of filtering high frequency common mode noise. The power is delivered through the power line 60 and first coil 62A of the choke to a power delivery capable communication port 70 (which acts as a load). A return line 90 which goes from the load through the choke's second coil 62B and back to the power supply completes the circuit.

The noise filter circuit may include a capacitor. In this example, the circuit includes line by-pass capacitors 65A and 65B between the live power line 60 and ground and the power return line 90 and ground. The line by-pass capacitors are positioned downstream of the choke (in this context the term ‘downstream’ means further away from the power supply and the term ‘upstream’ means closer to the power supply). The line by-pass capacitors act to filter out common mode noise.

As many network device power supplies and their associated higher voltage power supply lines have a safety requirement to be able to cope with a very high voltage, considerably higher than the normal power supply output, for a period of time, the capacitors may have a relatively low capacitance. As a result the choke may have a relatively high inductance, for example 100 to 500 μH, so that reasonable noise reduction can be achieved even when the capacitance is low, for example 1-10 nF. When there is a relatively high inductance, voltage transients may be more serious as the voltage transient is proportional to the inductance. However, as explained above, the voltage transient may be reduced by turning ON a switch to complete a parallel power delivery line 50, before turning off the voltage to the port 70.

While not shown in FIG. 4, the noise filter circuit may also have components to filter differential noise, for example an across the line capacitor between the live and return power lines upstream of the common mode choke 62 and/or downstream of the line by-pass capacitors 65A, 65B.

FIG. 5 shows an example of a port power controller 200 and associated power line and ports. If the ports are PoE ports, then the port power controller is referred to as a PoE controller. The port power controller controls the delivery of high voltage power to a plurality of ports so that the ports can deliver the power to external devices. For example, after receiving a power down signal the port power controller may switch off power to all the ports which it controls. In another, example if the power down signal is only addressed to some of the ports it controls, then it may switch off the power to only those ports.

In the example of FIG. 5, the port power controller 200 controls the delivery of high voltage power to a plurality of ports 70A, 70B and 70C. The port power controller may for example be a microprocessor, ASIC, FPGA or other logic circuitry. It controls a respective switch 210A, 210B and 210C, such as a transistor, on the power line delivering power to each port. Ordinarily the switches 210A, 210C and 210B are ON and power is delivered to the respective ports. However, after receiving a power down signal for a port, the port power controller 200 turns off the switch corresponding to that port so that high voltage power can no longer be delivered through the port to an external device. Generally the port power controller will be configured to turn off all the switches for all ports it controls after receiving a power down signal. However, in another example, if the network device controller 40 has capability to send a power down signal requesting power down of only certain specified ports or a certain number of ports, then the port power controller 200 may turn off the switches only relating to those ports. There may be several port power controllers 200 each controlling several ports and in that case the controller 40 may send the power down signal to all the port power controllers or a subset thereof.

FIG. 5 also shows how the parallel first power line 60 and second power lines 50 merge downstream after the noise filter 62 and second power line switch 52, into a single power line that subsequently splits to delivers power to each of the ports 70A, 70B and 70C. The switch 52 is controlled by the network device controller 40. By turning ON the switch 52 shortly before the port power controller 200 turns off power to one or more ports, the second parallel power line 50 is able to conduct some of the power before the power to the port is turned off. This helps to reduce the voltage transient in the inductor of the noise filter 62 caused by turning off the power to the one or more ports.

If power is turned off for only one of the ports, e.g. port 70A, then the remaining ports 70B, 70C may still draw power from the power supply and power lines 50 and 60. The power down operation for port 70A includes the power controller 200 turning off the switch 210A. This may cause a voltage transient in the inductor of noise filter 62 as less current will be drawn through the inductor. By turning on switch 52 before performing the power down operation for port 70A, the voltage transient can be reduced. As a result any voltage transient transmitted to ports 70B and 70C or other components may be reduced.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A network device comprising
a power supply;
a communication port capable of sending and receiving data over a wired link and capable of delivering power from the power supply over a wired link to an external device;
a first power line between the power supply and the communication port, the first line including an inductor;
a second power line between the power supply and the communication port, said second power line being in parallel with the first power line, the second power line having a switch; when the switch is ON power may be conducted over the second power line and when the switch is OFF the power is not conducted over the second power line;
a controller to turn the switch ON before sending a power down signal for the port and to turn the switch OFF after a power down operation for the port is completed.

2. The network device of claim 1 wherein the network device has a plurality of power supplies, the power from the power supplies is pooled to provide a single power source to the network device and the controller is to send a power down signal to the communication port in response to determining that one of the power supplies has failed or is overloaded.

3. The network device of claim 1 wherein the network device has a plurality of communication ports capable of delivery power and a port power controller to control whether or not the communication ports deliver power.

4. The network device of claim 1 wherein the controller is to turn the switch ON a few micro seconds before sending the power down signal.

5. The network device of claim 1 wherein the controller is to turn the switch OFF in response to receiving a signal indicating that the port has completed a power down operation.

6. The network device of claim 1 wherein the controller is to turn the switch OFF a predetermined period of time after sending the power down signal.

7. The network device of claim 1 wherein the inductor is a common mode choke.

8. The network device of claim 1 wherein the network device includes a DC-DC converter circuit between the power supply and the controller to convert power from the power supply to a lower voltage for use by the controller.

9. A network device comprising
a power supply
a Power over Ethernet (PoE) port;
a PoE controller to control whether power from the power supply is delivered to the PoE port;
a first power line between the power supply and the PoE port, the first line including a noise filter comprising an inductor;
a switch which completes a second power line between the power supply and the PoE port when the switch is ON and breaks the second power line when the switch is OFF,
a network device controller to turn the switch ON before sending a power down signal to the PoE controller and to turn the switch OFF after a power down operation is completed.

10. The network device of claim 9 comprising a plurality of power supplies which are connected to supply power jointly to components of the network device; and wherein the network device controller is to turn the switch ON and send a power down signal in response to determining that one of the power supplies is overloaded or has failed.

11. The network device of claim 9 wherein the network device has a plurality of PoE ports associated with the PoE controller and the PoE controller is to turn off PoE power delivery to the PoE ports in response to receiving a power down signal from the network device controller.

12. The network device of claim 9 wherein the switch is a transistor.

13. The network device of claim 9 wherein the inductor is a common mode choke and wherein the noise filter further comprises a line by-pass capacitor.

14. A method of reducing a transient voltage through a noise filter in a network device after a power delivery capability of a communication port is turned off; the method comprising delivering power from a power supply to a communication port along a first path including a noise filter which comprises an inductor and determining, by a controller, to send a power down signal to turn off the delivery of power to the communication port and sending the power down signal only after first turning on a switch to complete a parallel path which shares delivery of power to the communication port.

15. The method of claim 14 wherein a power supply delivers power at a higher voltage to the communication port and a power at a lower voltage to other network device components and wherein the delivery of higher voltage power to the communication port is turned off in response to the power down signal.
